(19) United States
(12) Patent Application Publication
(10) Pub. No.: US 2016/0192487 A1
(43) Pub. Date: Jun. 30, 2016

(54) Via Transition and Method of Fabricating the Same

(71) Applicant: TELEFONAKTIEBOLAGET L M ERICSSON (PUBL), Stockholm (SE)

(72) Inventors: Bo Zhou, Nanjing, Jiangsu (CN); Kun Liu, Nanjing, Jiangsu (CN); Junyou Chen, Nanjing, Jiangsu (CN)

(21) Appl. No.: 14/911,410

(22) PCT Filed: Aug. 12, 2013
(86) PCT No.: PCT/CN2013/081266

§ 371 Date: Feb. 10, 2016

(51) Int. Cl. H05K 1/11; H05K 3/46; H05K 3/10; H05K 3/40; H05K 1/09; H05K 1/03

(52) U.S. Cl. CPC H05K 1/115; H05K 1/09; H05K 1/0306; H05K 1/0313; H05K 3/10; H05K 3/4038; H05K 3/46; H05K 2201/0141; H05K 2201/0175

(57) ABSTRACT

The present disclosure provides a via transition, comprising: two end segments; high-impedance segments and low-impedance segments. The high-impedance segments and the low-impedance segments are alternately arranged between the two end segments, and the via transition is formed in a substrate. The disclosure also provides a power divider comprising the via transition and a method of fabricating the low-pass via transition.

### TECHNICAL FIELD

The present disclosure generally relates to multilayer integrated circuits, and particularly, to a via transition and a method of fabricating the same.

### BACKGROUND

This section is intended to provide a background to the various embodiments of the technology described in this disclosure. The description in this section may include concepts that could be pursued, but are not necessarily ones that have been previously conceived or pursued. Therefore, unless otherwise indicated herein, what is described in this section is not prior art to the description and/or claims of this disclosure and is not admitted to be prior art by the mere inclusion in this section.

Via transitions are widely used in multilayer integrated circuits to interconnect parallel transmission lines arranged on different layers of a circuit substrate.

Being structured as shown in FIG. 1, conventional via transitions suffer from significant electrical discontinuities due to radiation and reflection, and thus have a very limited application bandwidth. Typically, to guarantee that the S-parameter S₁₁ is better than −14.99 dB and S₂₁ is better than −1 dB, a conventional via transition must operate in a frequency range from 0 to 2.579 GHz, as illustrated in FIG. 2.

To overcome the bandwidth limitation of the conventional via transitions, broadband via transitions have been proposed, wherein complemented elements (such as vias, cavities, pads and quasi-coaxial) are used to eliminate electrical discontinuities of via transitions (see [1]-[3], for example).

The addition of complemented elements brings considerable complexity to the manufacture of via transitions. Moreover, the bandwidth of the via transitions using complemented elements is not broad enough to reach the millimeter wave frequency band.

### SUMMARY

In view of the foregoing, an object of the present disclosure is to obviate at least one of the above disadvantages by providing a newly-structured via transition. Another object of the present disclosure is to provide a method of fabricating such a via transition.

In a first aspect of the disclosure, there is provided a via transition formed in a substrate. The via transition comprises high-impedance segments and low-impedance segments. The high-impedance segments and the low-impedance segments are alternately arranged between two end segments of the via transition.

Being structured to include high-impedance segments and low-impedance segments alternately arranged between two end segments, the via transition according to the first aspect of the disclosure has a simpler structure compared with the via transitions using extra complemented elements. Furthermore, thanks to the stepped impedance low-pass filter structure formed by the alternately arranged high-impedance segments and low-impedance segments, the radiation loss and crosstalk of the via transition can be effectively reduced, and the bandwidth of the via transition can be significantly increased accordingly.

In a second aspect of the disclosure, there is provided a method for forming in a substrate a via transition according to the first aspect of the disclosure. The method comprises the step of forming each of the end segments, the high-impedance segments and the low-impedance segments extending through one or more of a plurality of dielectric layers. Next, the dielectric layers are stacked in such a manner that the high-impedance segments and the low-impedance segments are alternately arranged between the two end segments. After that, all the stacked layers are laminated and co-fired to form a multilayered structure.

According to the second aspect of the disclosure, the via transmission according to the first aspect of the disclosure can be fabricated in a cost-effective manner.

### BRIEF DESCRIPTION OF THE DRAWINGS

The above and other objects, features, and advantages of the present disclosure will become apparent from the following descriptions on embodiments of the present disclosure with reference to the drawings, in which:

FIG. 1 is a perspective view of a via transition according to the prior art;

FIG. 2 is a plot illustrating simulated amplitude-frequency curves of S-parameters S₁₁ and S₂₁ of the via transition according to the prior art;

FIG. 3 is a perspective view of a via transition according to an embodiment of the present disclosure;

FIG. 4 schematically illustrates a top view, a bottom view and a side view of the via transition according to the embodiment of the present disclosure;

FIG. 5 is a diagram illustrating an equivalent circuit of the via transition according to the embodiment of the present disclosure;

FIG. 6 is a plot illustrating simulated and measured amplitude-frequency curves of S-parameters S₁₁ and S₂₁ of the via transition according to the embodiment of the present disclosure; and

FIG. 7 is a flowchart illustrating a method of fabricating the via transition according to the embodiment of the present disclosure.

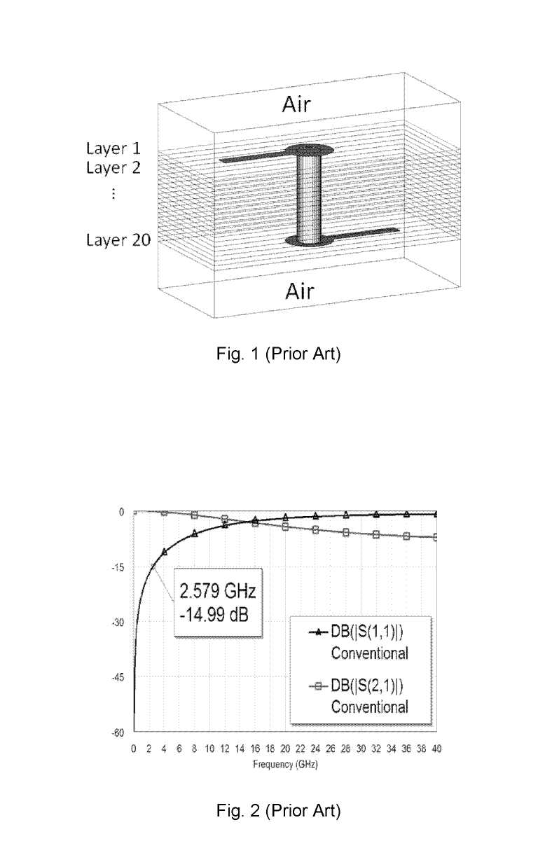

It should be noted that various parts in the drawings are not drawn to scale, but only for an illustrative purpose, and thus should not be understood as any limitations and constraints on the scope of the present invention.

### DETAILED DESCRIPTION OF EMBODIMENTS

According to the general concept of the present disclosure, a via transition formed in a substrate may be structured to comprise high-impedance segments and low-impedance segments. The high-impedance segments and the low-impedance segments are alternately arranged between two end segments of the via transition.

Without extra complemented elements, the proposed via transition can be fabricated easily compared with those proposed in [1]-[3]. Furthermore, by virtue of the stepped impedance low-pass filter structure formed by the alternately arranged high-impedance segments and low-impedance segments in a substrate, the radiation loss and crosstalk of the via transition can be effectively reduced, and the bandwidth of the via transition can be significantly increased.

Accordingly, due to its structural simplicity, the proposed via transition remarkably improves in production yield as compared with those proposed in [1]-[3]. Furthermore, the performance of the proposed via transition can be kept reasonable at high frequency, even if the proposed via transition is made of low-cost metal (such as copper, aluminum, ferrum etc.) instead of gold. Thereby, the cost of manufacturing the proposed via transition is significantly decreased.

CN 202205870 U and CN 101056094 A propose a high-power low-pass filter with a high suppression performance and a high-power low-pass filtering coaxial impedance converter, respectively. Due to the specific purposes for which the proposed filter and converter are used and hence the necessity of constructing them by connecting transmission lines via mechanical parts, CN 202205870 U and CN 101056094 A cannot be resorted to when the problem to be solved is how to eliminate electrical discontinuities of a via transition formed in a substrate.

The substrate wherein the via transition is formed may be, for example, a Low Temperature Co-fired Ceramic (LTCC), High Temperature Co-fired Ceramic (HTCC), Liquid Crystal Polymer (LCP) or organic Printed Circuit Board (PCB) substrate. Preferably, the LTCC substrate is made of Ferro A6S having a dielectric constant of 5.9 and a loss tangent of 0.002. Each LTCC dielectric layer may have a post-fired thickness of 100 um.

For the ease of manufacturing, each segment may be preferably formed to extend through one or more layers of the substrate.

The proposed via transition may be comprised in a branch-line, a power divider, or any other device wherein a via transition is required.

Hereinafter, an exemplary via transition according to the above general concept will be described in detail with reference to the drawings. However, it is to be understood that the details (such as the number of segments, the geometry and dimension of each segment, etc.) of the exemplary via transition are just given for facilitating the understanding of the present disclosure, rather than limiting the present disclosure. Various alternations and modifications obvious to those skilled in the art can be made without departing from the scope of the disclosure.

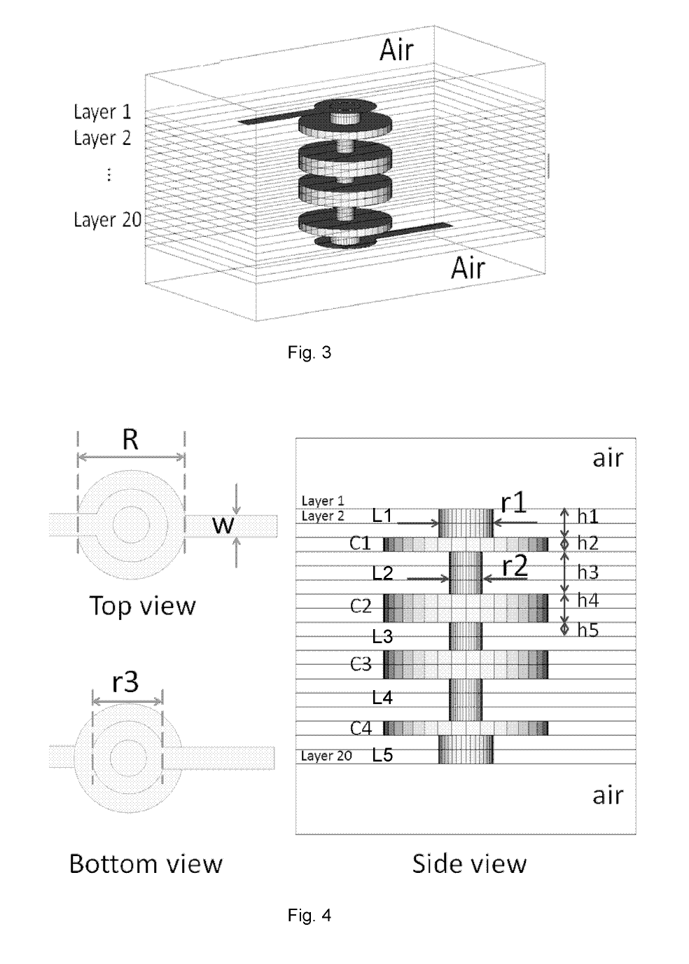

FIG. 3 schematically illustrates a perspective view of the exemplary via transition according to the present disclosure. FIG. 4 illustrates a front view, a bottom view and a side view of the via transition. In FIGS. 3 and 4, two transmission lines are additionally shown to be coupled with the two end segments L1 and L5, respectively. Depending on application scenarios, the transmission lines may be striplines or microstrips.

As expressly marked in the side view illustrated in the FIG. 4, the via transition comprises two end segments L1 and L5, four low-impedance segments C1, C2, C3 and C4, and three high-impedance segments L2, L3 and L4. The low-impedance segments C1, C2, C3 and C4 and the high-impedance segments L2, L3 and L4 are alternately arranged between the end segments L1 and L5.

The specific numbers of the low-impedance segments and the high-impedance segments given here achieve a tradeoff between the performance of the via transition and the complexity in manufacturing the via transition. As mentioned above, those skilled in the art may figure out other numbers of the low-impedance segments and the high-impedance segments according to the specific design target.

In practical manufacturing, all the segments may be shaped uniformly and aligned coaxially, and the impedance of each segment can be easily controlled by adjusting the cross-sectional area and/or the length of the segment.

By way of example, as illustrated in FIGS. 3 and 4, all the end segments L1 and L5, the low-impedance segments C1, C2, C3 and C4, and the high-impedance segments L2, L3 and L4 are the same shape of cylinder and coaxially aligned. The low-impedance segments C1, C2, C3 and C4 each has a smaller cross-sectional area than any of the end segments L1 and L5, and the high-impedance segments L2, L3 and L4 each has a larger cross-sectional area than any of the end segments L1 and L5. As will be appreciated by those skilled in the art, the cross-sectional areas of the low-impedance segments C1, C2, C3 and C4 may be different from each other, although they are shown to be identical in FIGS. 3 and 4. The same also applies to the cross-sectional areas of the high-impedance segments L2, L3 and L4.

As can be further seen from the side view of FIG. 4, the substrate wherein the via transition is formed have 20 layers. The low-impedance segments C1 and C4 each extends through a single layer of the substrate. The end segments L1 and L5, the low-impedance segments C2 and C3 and the high-impedance segment L3 each extends through two layers of the substrate. The high-impedance segments L2 and L4 each extends through three layers of the substrate.

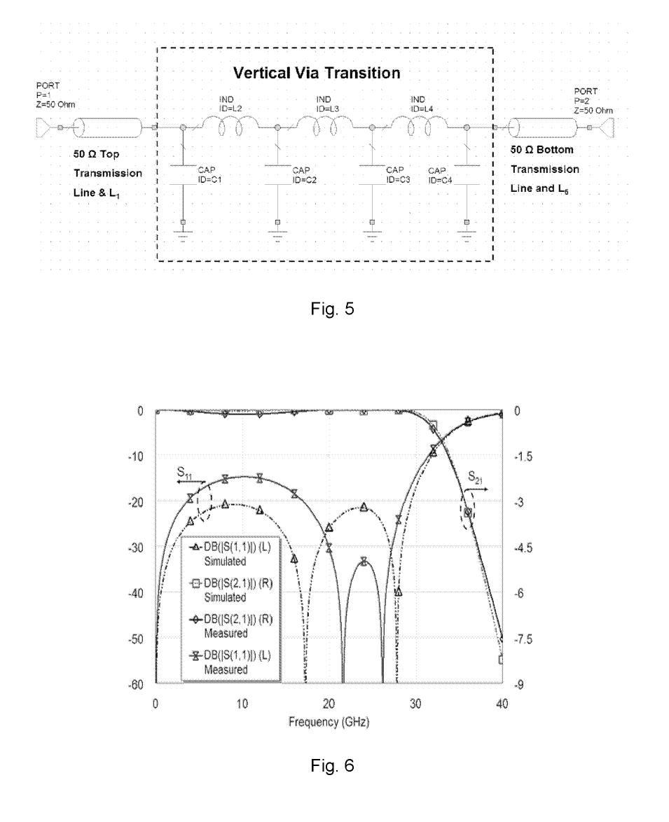

FIG. 5 schematically illustrates an equivalent circuit of the exemplary via transition shown in FIGS. 3 and 4. As expressly marked in FIG. 5, the high-impedance segments L2, L3 and L4 equate to inductors connected in series, the low-impedance segments C1, C2, C3 and C4 equate to capacitors connected in parallel, the end segment L1 and the top transmission line coupled thereto equates to a resistor, and the end segment L5 and the bottom transmission line coupled thereto equates to a resistor.

Given dimensions and material of the proposed via transition, parameters of equivalent elements within the equivalent circuit of the via transition can be determined. Accordingly, S-parameters of the via transition can be determined. Preferably, the proposed via transition as well as the transmission lines are made of gold or silver which has a very high electrical conductivity, so that the performance of the via transition is excellent at high frequency.

For the ease of description, certain reference signs are given in FIG. 4 to denote the dimensions of the segments. As specifically shown in FIG. 4, r1 denotes the diameter of the top end segment L1; R denotes the diameter of the low-impedance segments C1, C2, C3 and C4; r2 denotes the diameter of the high-impedance segments L2, L3 and L4; r3 denotes the diameter of the bottom end segment L5; h1 denotes the height of the top end segment L1; h2 denotes the height of the low-impedance segments C1 and C4; h3 denotes the height of the high-impedance segments L2 and L4; h4 denotes the height of the low-impedance segments C2 and C3; h5 denotes half of the height of the high-impedance segment L3; and W denotes the width of the transmission lines respectively coupled to the end segments L1 and L5.

Supposing R=0.6 mm, r1=0.18 mm, r2=0.12 mm, r3=0.22 mm, h1=h4=0.2 mm, h2=h5=0.1 mm, h3=0.3 mm, w=0.14 mm and the via transition and transmission lines are made of gold, the inductors caused by the high-impedance segments L2 and L4 would have the same inductance of 0.62 nH, the inductor caused by the high-impedance segment L3 would have an inductance of 0.42 nH, the capacitors caused by the low-impedance segments C1 and C4 would have the same capacitance of 0.03 pf, the capacitors caused by the low-impedance segments C2 and C3 would have the same capacitance of 0.13 pf, and the resistor caused by the top end segment L1 and the top transmission line would have an resistance of 50 ohm, which is same as that of the resistor caused by the bottom end segment L5 and the bottom transmission line.

In FIG. 6, simulated and measured amplitude-frequency curves of S-parameters S₁₁ and S₂₁ of the via transition using the above-listed dimensions are illustrated. As shown in the plot, the measured is better than −15 dB and the measured S₂₁ is better than −1 dB from 0 to 30 GHz. That is, subject to the same conditions of <−15 dB and S₂₁>−1 dB, the application bandwidth of the proposed via transition is 30/2.579≈12 times more than that of the conventional via transition, and does reach the millimeter wave frequency band.

To determine actual dimensions of the proposed via transition based on desirable design indices such as S-parameters, insertion losses at certain frequencies may be firstly derived from the desirable design indices. Then, approximate dimensions of the via transition may be calculated based on the derived insertion losses using the following formula (1), which characterizes the insertion loss characteristic of a stepped impedance low-pass filter:

$${P}_{L} = 101 g \{ 1 + {h}^{2} {T}_{n}^{2} [ \frac{sin ( \frac{ω}{{ω}_{c}} {θ}_{0} )}{sin {θ}_{0}} ] \} \qquad ( 1 )$$

where P_{L} denotes the insertion loss, θ₀ is the average electrical length of the high-impedance and low-impedance segments at the cutoff frequency (ωₑ), Tₙ(x) is the chebyshev polynomial of order n, n is the number of high-impedance and low-impedance segments, and

h²=anti 1g(L_{AR}/10)−1 (2)

where L_{AR} is the maximum dB attenuation in the pass band.

Next, the actual dimensions of the proposed via transition may be obtained by optimizing the approximate dimensions to minimize the error between the actual insertion loss characteristic resulted from the approximate dimensions and the insertion loss characteristic (1) used for calculating the approximate dimensions. This optimization can be achieved numerically by using Microwave Office Simulators such as EMsight.

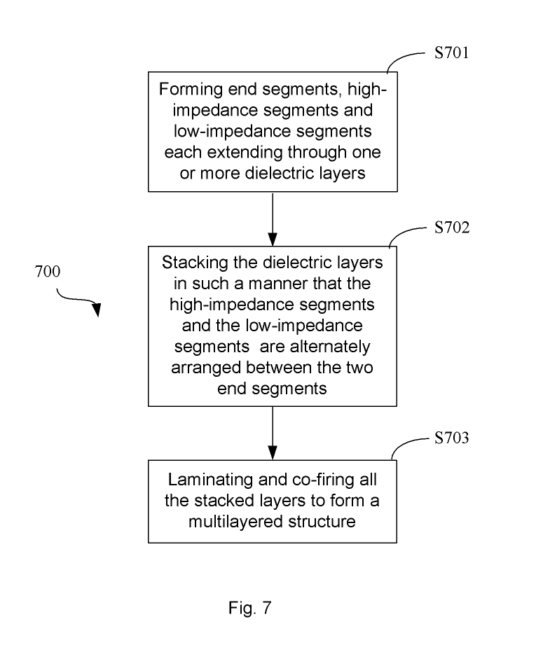

FIG. 7 illustrates a method of fabricating the exemplary via transition according to the embodiment of the present invention. It should be noted that fabricating steps which are not relevant to the present disclosure are omitted for clarity.

As illustrated in FIG. 7, initially, the end segments L1 and L5, the high-impedance segments L2, L3 and L4, and the low-impedance segments C1, C2, C3 and C4, each of which extending through one or more of a plurality of dielectric layers, are formed, in step S701.

Then, in step S702, the dielectric layers are stacked in such a manner that the high-impedance segments L2, L3 and L4 and the low-impedance segments C1, C2, C3 and C4 are alternately arranged between the two end segments L1 and L5.

After that, all the stacked layers are laminated and co-fired to form a multilayered structure, in step S703.

Preferably, two transmission lines may be formed respectively on the top and the bottom dielectric layers of the plurality of dielectric layers to directly couple to the end segments L1 and L5, during or after the process of fabricating the via transition.

The present disclosure is described above with reference to the embodiments thereof. However, those embodiments are provided just for illustrative purpose, rather than limiting the present disclosure. The scope of the disclosure is defined by the attached claims as well as equivalents thereof. Those skilled in the art can make various alternations and modifications without departing from the scope of the disclosure, which all fall into the scope of the disclosure.

### REFERENCES

[1] Y. C. Lee and C. S. Park.: ‘A 60 GHz stripline BPF for LTCC System-in-Package applications’, IEEE Microwave symposium Digest 2005, pp. 1-4.
[2] I. Ju, I. B. Y, H. S. Lee and S. H. Oh.: ‘High performance vertical transition from DC to 70 GHz for system-on package applications’, 38th European Microwave Conference, 2008, pp. 1338-1341.
[3] R. E. Amaya, M. Li, K. Hettak and C. J. Verver.: ‘A broadband 3D vertical microstrip to stripline transition in LTCC using a quasi-coaxial structure for millimetre-wave SOP applications’, 40th European Microwave Conference, 2010, pp. 109-112.

1-17. (canceled)

18. A via transition, comprising:
two end segments;
high-impedance segments; and
low-impedance segments,
wherein the high-impedance segments and the low-impedance segments are alternately arranged between the two end segments, and the via transition is formed in a substrate.

19. The via transition of claim 18, wherein each segment extends through one or more layers of the substrate.

20. The via transition of claim 18, wherein the substrate is a Low Temperature Co-fired Ceramic (LTCC), High Temperature Co-fired Ceramic (HTCC), Liquid Crystal Polymer (LCP) or organic Printed Circuit Board (PCB) substrate.

21. The via transition of claim 20, wherein the LTCC substrate is made of Ferro A6S having a dielectric constant of 5.9 and a loss tangent of 0.002.

22. The via transition of claim 20, wherein each LTCC dielectric layer has a post-fired thickness of 100 um.

23. The via transition of claim 18, wherein the number of the low-impedance segments is four, and the number of the high-impedance segments is three.

24. The via transition of claim 18, wherein each segment has a cylindrical shape and all the segments are coaxially aligned.

25. The via transition of claim 18, wherein each of the high-impedance segments has a smaller cross-sectional area than any of the end segments, and each of the low-impedance segments has a larger cross-sectional area than any of the end segments.

26. The via transition of claim 18, wherein the two end segments are directly coupled to two transmission lines, respectively.

27. The via transition of claim 26, wherein the via transition and the transmission lines are made of gold or silver.

28. A power divider comprising the via transition according to claim 18.

29. A method for forming in a substrate a via transition which comprises two end segments and high-impedance and low-impedance segments alternately arranged between the two end segments, the method comprising:
forming each of the end segments, the high-impedance segments and the low-impedance segments extending through one or more of a plurality of dielectric layers;
stacking the dielectric layers in such a manner that the high-impedance segments and the low-impedance segments are alternately arranged between the two end segments; and
laminating and co-firing all the stacked layers to form a multilayered structure.

30. The method of claim 29, wherein the substrate is a Low Temperature Co-fired Ceramic (LTCC), High Temperature Co-fired Ceramic (HTCC), Liquid Crystal Polymer (LCP) or organic Printed Circuit Board (PCB) substrate.

31. The method of claim 29, wherein the number of the low-impedance segments is four, and the number of the high-impedance segments is three.

32. The method of claim 29, wherein each segment has a cylindrical shape and all the segments are coaxially aligned.

33. The method of claim 29, wherein each of the high-impedance segments has a smaller cross-sectional area than any of the end segments, and each of the low-impedance segments has a larger cross-sectional area than any of the end segments.

34. The method of claim 29, further comprising
forming a transmission line on a top dielectric layer of the plurality of dielectric layers to directly couple the transmission line to one of the end segments; and
forming another transmission line on a bottom layer of the plurality of dielectric layers to directly couple the another transmission line to the other of the end segments.
